(19) United States
(12) Patent Application Publication
(10) Pub. No.: US 2014/0342570 A1
(43) Pub. Date: Nov. 20, 2014

(54) ETCH PROCESS HAVING ADAPTIVE CONTROL WITH ETCH DEPTH OF PRESSURE AND POWER

(71) Applicant: APPLIED MATERIALS, INC., Santa Clara, CA (US)

(72) Inventors: Kenny Linh Doan, San Jose, CA (US); Daisuke Shimizu, Saratoga, CA (US); Jong Mun Kim, San Jose, CA (US); Sergio Fukuda Shoji, San Jose, CA (US); Justin Phi, Milpitas, CA (US); Katsumasa Kawasaki, San Jose, CA (US); Kartik Ramaswamy, San Jose, CA (US); James P. Cruse, Santa Cruz, CA (US)

(73) Assignee: APPLIED MATERIALS, INC., Santa Clara, CA (US)

(21) Appl. No.: 13/912,533

(22) Filed: Jun. 7, 2013

Related U.S. Application Data
(60) Provisional application No. 61/824,006, filed on May 16, 2013.

(51) Int. Cl. H01L 21/3065

(52) U.S. Cl. CPC H01L 21/3065
USPC 438/714

(57) ABSTRACT

The disclosure concerns a plasma-enhanced etch process in which chamber pressure and/or RF power level is ramped throughout the etch process.

### CROSS-REFERENCE TO RELATED APPLICATIONS

This application claims the benefit of U.S. Provisional Application Ser. No. 61/824,006, filed May 16, 2013 entitled ETCH PROCESS HAVING ADAPTIVE CONTROL WITH ETCH DEPTH OF PRESSURE AND POWER, by Kenny Linh Doan, et al.

### BACKGROUND

1. Technical Field

The disclosure concerns plasma-enhanced etch processes for fabrication of microelectronic devices such as semiconductor integrated circuits.

2. Background Discussion

Fabrication of semiconductor integrated circuits has progressed toward smaller device sizes. Typically, contact holes are etched through insulating material between conductor structures in different layers. The contact holes may be nominally 50 nm in diameter and in excess of 2000 nm in length, so that the holes have an extremely high aspect ratio of about 40:1. Such a high aspect ratio makes the process vulnerable to failure due instability or interruption in plasma generation. One problem is that the etch process must be sufficiently selective so that it does not attack an underlying etch stop layer at the bottom of the hole. The etch stop layer may be a material different from the insulating material through which the hole is etched. The term etch selectivity may be defined as the etch rate at which the process etches the insulating material divided by the etch rate at which the process etches the underlying barrier layer. The problem of etch selectivity to the etch stop layer was conventionally addressed by setting the chamber to a lower pressure before the etch process reached the etch stop layer. For example, in one etch processes, the chamber pressure is set to about 20 milliTorr (mT) at the start. Then, after the etch depth reaches about 33% of the ultimate depth (e.g., of 2200 nm), the chamber pressure is set to 15 mT. Then, after the etch depth reaches about 66% of the ultimate depth, the chamber pressure is set to 10 mT and held there until the ultimate depth is reached. These abrupt changes in chamber pressure create plasma instabilities (such as arcing that can damage devices) to which the high aspect ratio opening is particularly vulnerable.

This problem was addressed by introducing transition steps during which the step-wise changes in chamber pressure are carried out. Each transition step consists of reducing (or turning off) plasma source power, setting the chamber pressure to the lower value, and then restoring the plasma source power to its former level. During each transition step, the plasma power is sufficiently low to prevent significant plasma instability during the abrupt change in chamber pressure. However, this approach creates yet another problem, namely that the plasma ion density or energy is insufficient during the transition step to avoid polymer build-up inside each hole due to continued presence of carbon-rich process gases within the process chamber. Such build-up of polymer inside the holes leads to etch stop and device failure. Therefore, there is a need to improve etch selectivity to the barrier layer without risking device damage.

Another problem encountered in plasma etching of holes with a 40:1 aspect ratio is bending, in which the bottom portion of each hole is not coaxial with the top portion of the hole. One approach to this problem is to select a high RF power level to increase plasma ion energy. While this approach can reduce bending, it increases the rate at which plasma sputters the photolithographic mask defining the holes. For etching holes with a 40:1 aspect ratio, if the RF power is set to a level sufficient to prevent bending, then the product of the mask sputtering rate and the required etch time exceeds the initial thickness of the mask, so that the mask is completely removed prior to completion of the etch process. This leads to device failure. Therefore, there is a need to prevent bending without risking loss of the photolithographic mask during processing.

There are other problems encountered with etching holes with an aspect ratio of at least 40:1. For example, the top and bottom of the hole may be non-concentric. Specifically, the hole shape defined by the mask at the top of the hole is circular, while the final hole shape at the bottom is non-circular (e.g., elliptical, eccentric, star-shaped or the like). Another problem is bowing, in which the hole diameter is larger in a zone between the top and bottom of the hole. A related problem is that non-concentricity, bending, bowing and loss of the mask reduce control over critical dimension in the fabricated structure.

### SUMMARY

A method of processing a workpiece in a plasma reactor chamber comprises: (a) defining a starting chamber pressure and an ending chamber pressure at which a desired etch selectivity of an etch process to an underlying barrier layer is realized, (b) defining an etch time and computing a pressure ramping rate as a difference between the starting and ending chamber pressures divided by the etch time, (c) providing in the chamber a plasma containing etchant species, (d) initializing a chamber pressure in the chamber at the starting chamber pressure, and ramping the chamber pressure at the pressure ramping rate.

The method may further comprise providing a user interface configured to receive values of the starting and ending chamber pressures, and controlling the chamber pressure with a digital control system in response to the user interface. In one embodiment, the ramping comprises generating successive chamber pressure commands in the digital control system representing successive microsteps of decreasing pressure levels. In one embodiment, the pressure difference between successive microsteps is sufficiently small to cause the chamber pressure to decrease in a continuous ramp. In a related embodiment, each of the successive microsteps corresponds to a digital quantization size of the digital control system.

In accordance with another aspect, a method is provided for processing a workpiece in a plasma reactor chamber comprising an RF power applicator. The method comprises: (a) defining a starting RF power level and an ending RF power level sufficient to prevent bowing at the bottom of an etched opening, (b) defining an etch time, (c) computing an RF power ramping rate as a difference between the starting and ending RF power levels divided by the etch time, (d) providing in the chamber a plasma containing etchant species, (e) initializing an RF power level for the RF power applicator at the starting RF power level, and (f) ramping the RF power level pressure at the RF power ramping rate.

The method may further comprise providing a user interface configured to receive values of the starting and ending RF power levels, and controlling the RF power level with a digital control system in response to the user interface. In one embodiment, the ramping comprises generating successive RF power level commands in the digital control system representing successive microsteps of increasing RF power levels. In one embodiment, the pressure difference between successive microsteps is sufficiently small to cause the RF power level to increase in a continuous ramp. In an embodiment, each of the successive microsteps corresponds to a digital quantization size of the digital control system.

In one embodiment, the starting RF power level is one a minimum for sustaining an etch process. In one embodiment, the ending RF power level is sufficient to prevent bowing near a bottom of an etched opening having an aspect ratio on the order of approximately 40:1.

### BRIEF DESCRIPTION OF THE DRAWINGS

So that the manner in which the exemplary embodiments of the present invention are attained can be understood in detail, a more detailed description of the invention, briefly summarized above, may be obtained by reference to the embodiments thereof which are illustrated in the appended drawings. It is to be appreciated that certain well known processes are not discussed herein in order to not obscure the invention.

FIGS. 1A-1C depict the problem of non-concentricity, of which FIG. 1A depicts a structure in which an opening is etched, FIG. 1B depicts a cross-sectional view taken along lines 1B-1B of FIG. 1A, FIG. 1C depicts a cross-sectional view taken along lines 1C-1C of FIG. 1A in which the eccentricity is elliptical.

FIG. 2 is an elevational cross-sectional view of a portion of a semiconductor wafer depicting bowing in a high aspect ratio opening.

FIG. 3 is an elevational cross-sectional view of a portion of a semiconductor wafer depicting bending of a high aspect ratio opening.

FIG. 4 is a simplified block diagram depicting a plasma reactor in accordance with certain embodiments.

FIGS. 5A-5D are contemporaneous graphs illustrating operation of the plasma reactor of FIG. 4 in accordance with a first embodiment, of which FIG. 5A depicts digital pressure command value as a function of time, FIG. 5B (solid line) depicts actual chamber pressure as a function of time, FIG. 5C depicts etch depth as a function of time and FIG. 5D is an enlarged view of a superposition of a portions of FIGS. 5A and 5B.

FIG. 6 is a simplified block diagram of a method corresponding to FIGS. 5A-5D.

FIGS. 7A-7D are contemporaneous graphs illustrating operation of the plasma reactor of FIG. 4 in accordance with a second embodiment, of which FIG. 7A depicts a digital RF power command value as a function of time, FIG. 7B (solid line) depicts actual RF power or plasma ion energy as a function of time, FIG. 7C depicts etch depth as a function of time and FIG. 7D depicts mask thickness as a function of time.

FIG. 8 is a simplified block diagram of a method corresponding to FIGS. 7A-7D.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

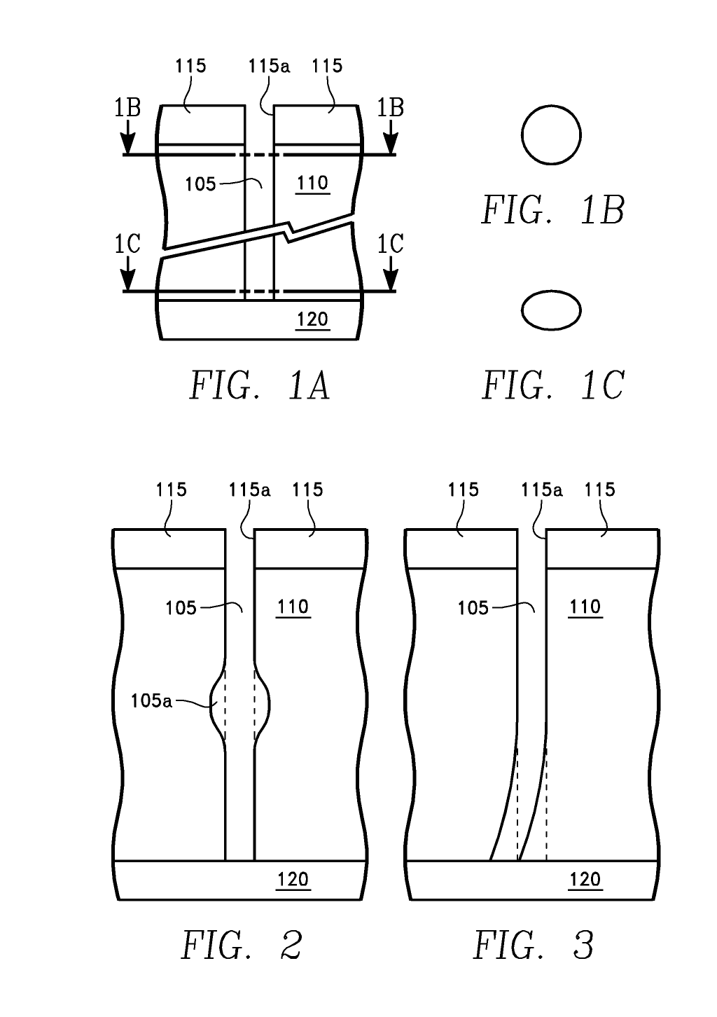

FIG. 1A depicts etching of a high aspect ratio opening or hole 105 in a thin film structure on a workpiece such as a semiconductor wafer 110. A photolithographic mask 115 overlies the workpiece surface and has a circular opening 115a defining the hole 105. Ideally, the hole 105 stops at the top surface of an underlying etch stop layer 120. The hole shape (FIG. 1B) at the top of the hole 105 conforms with the circular shape of the mask opening 115a. The hole shape (FIG. 1C) at the hole bottom may be non-circular or non-concentric. FIG. 2 depicts how the hole 105 may have bowing in which one zone 105a of the hole 105 has a diameter greater than the rest of the hole 105. FIG. 3 illustrates bending, in which the axis of hole 105 near the hole bottom bends away from the axis at the top of the hole.

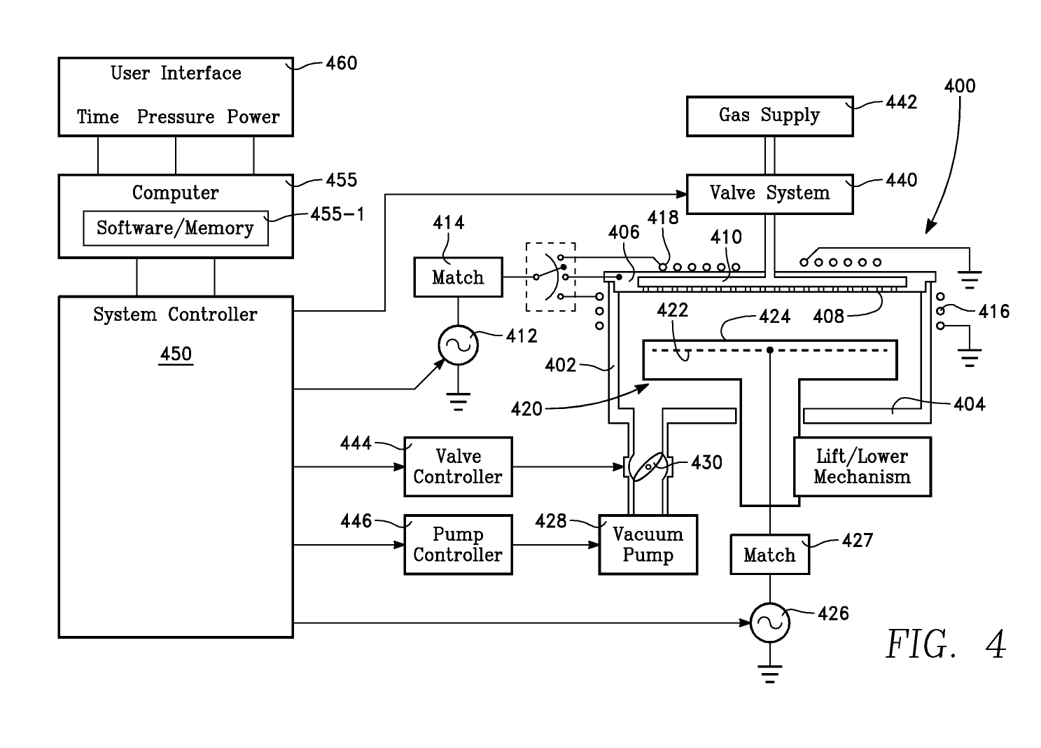

FIG. 4 depicts a plasma reactor capable of preventing bowing, bending and hole no concentricity (eccentricity) while providing improved etch selectivity to the etch stop layer and superior critical dimension control. The reactor of FIG. 4 includes a vacuum chamber 400 enclosed by a cylindrical side wall 402, a floor 404 and a ceiling 406. The ceiling 406 includes a gas distribution showerhead 408 and a gas manifold 410 coupled to the showerhead 408. The showerhead 408 in a first implementation operates as an RF electrode and may be coupled to an RF source power generator 412 through an impedance match 414. In another implementation, a coil such as a side coil 416 or an overhead coil 418 may be coupled to the RF source power generator 412 through the impedance match 414. A workpiece support pedestal 420 beneath the showerhead 408 includes a workpiece support electrode 422 beneath a workpiece support surface 424 coupled to an RF bias power generator 426 through an bias RF impedance match 427.

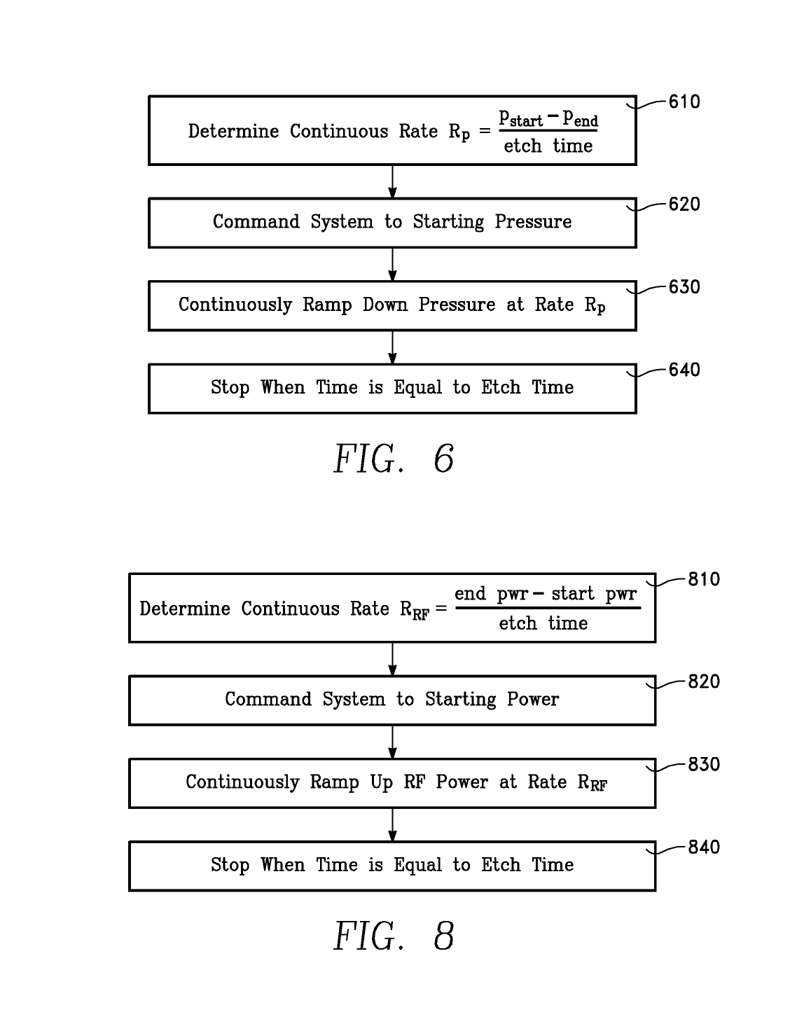

A vacuum pump 428 evacuates the chamber 400 through an exhaust valve 430. Gas is supplied to the gas distribution showerhead 408 through a gas flow rate valve system 440 from a process gas supply 442. The supply 442 may provide different process gas species to the valve system 440, which the valve system 440 may separately control. The exhaust valve 430 is controlled by an exhaust valve controller 444, which may include actuators to adjust the opening size of the valve 430. The vacuum pump 428 is controlled by a pump controller 446 which controls the pumping rate of the pump 428. A system controller 450 governs the valve controller 444, the pump controller 446, the gas valve system 440, the power level of the RF bias power generator 426 and the power level of the RF source power generator 412. A programmable computer 455 governs the system controller 450 and includes a memory 455-1 storing executable instructions. The memory 455-1 may be implemented as computer-readable media storing instructions for carrying out any of the methods disclosed herein, such the method of FIG. 6 or FIG. 8 or both, for example. A user interface 460 is coupled to the computer 455.

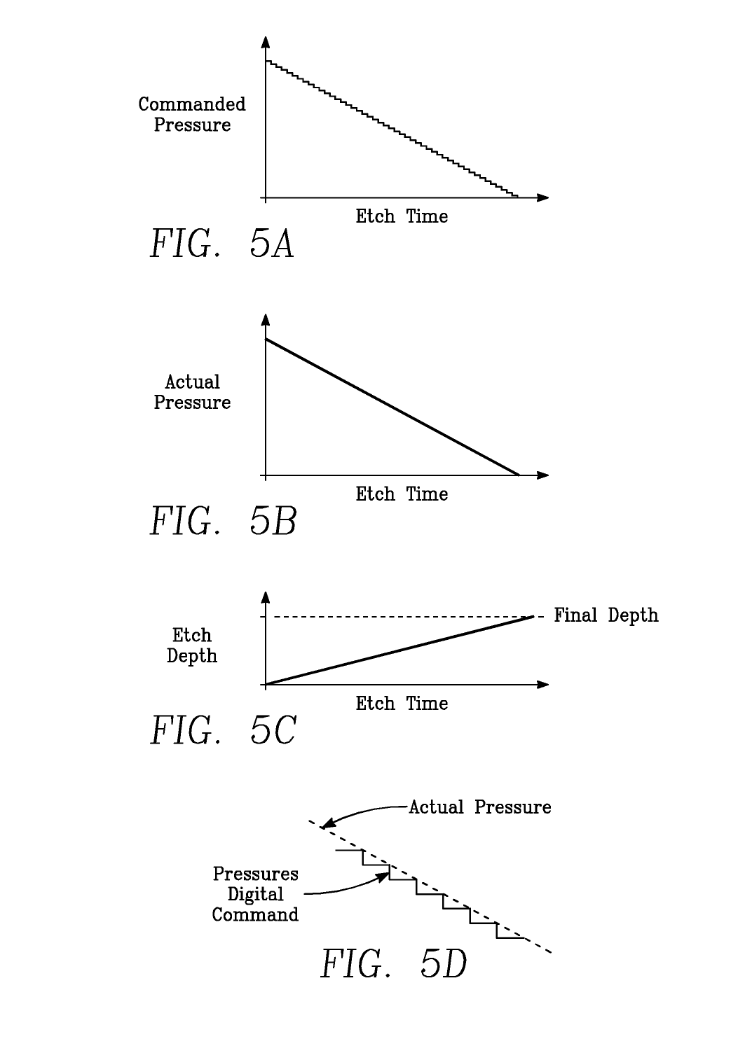

In accordance with a first embodiment, the user interface 460 provides the computer 455 with the following information entered by a user (or by an unillustrated superior control system): starting chamber pressure, ending chamber pressure and time (duration) of etch process. Referring to FIG. 5A, the computer 455 is programmed to command the system controller 450 to set the chamber pressure the starting pressure and commence the etch process, and continuously decreasing the chamber pressure at a computed rate. The rate is the difference between the starting and ending chamber pressures divided by the etch time. FIG. 5A shows the commanded chamber pressure being ramped down in micro steps, each microstep corresponding to a digital control sample size of the system controller 450. Typically, the system controller is implemented as a digital control system, the amplitude change of an individual microstep corresponding to the digital quantization of the digital control system implemented by the system controller 450. The duration of each microstep is preferably less than the time required for the chamber pressure to fully respond to a commanded pressure change represented by a single microstep. The response of the measured chamber pressure is too slow to follow the microsteps of FIG. 5A, and therefore follows the smooth ramp of FIG. 5B. FIG. 5C depicts how the etch depth increases during the duration of the etch process.

The solid line of FIG. 5D is a portion of the graph of pressure command microsteps of FIG. 5A. The dashed line of FIG. 5D is a contemporaneous portion of the graph of actual chamber pressure of FIG. 5B. The actual chamber pressure (dashed line of FIG. 5D) is continually changing to meet the latest microstep in the commanded pressure (solid line of FIG. 5D), and therefore follows a smooth continuous ramp trajectory as shown in the graph of FIG. 5D.

FIG. 6 depicts operation defined by the executable instructions of the memory 455-1 in accordance with the first embodiment corresponding to FIGS. 5A-5D. A first step is to determine the rate RP at which the pressure is to be ramped downwardly (block 610 of FIG. 6). The rate RP is computed as the difference between the starting and ending pressures divided by the etch time. The starting pressure, the ending pressure and the etch time are received from the user interface 460. The next step is to order the system controller 450 to initialize the pressure to the starting pressure (block 620 of FIG. 6). The controller 450 may accomplish this by controlling any of the pressure-determinative components, such as the exhaust valve controller 444 or the pump controller 446 or the valve system 440. Next, the computer outputs a succession of pressure commands in decreasing sequence of pressure values as depicted in FIG. 5A (block 630 of FIG. 6). The operation is halted at the end of the etch time (block 640 of FIG. 6).

The starting pressure is selected to optimize the etch rate or other process parameter, and may be as high as needed. The ending pressure is selected to provide sufficient etch selectivity to avoid punch through of the underlying etch stop layer 120 of FIG. 1, and therefore may be as low as needed. In one example, the starting pressure inside the chamber 100 was 120 mT and the ending pressure was 110 mT.

An advantage is that there are no abrupt changes in pressure. The pressure is changed beginning from a high pressure ideal at start of the etch process to a low pressure that is ideal for etch selectivity to the underlying etch stop layer, without requiring any interruption or discontinuity in RF power or plasma generation. In addition, we have discovered that the foregoing process of ramping the pressure solves the problems of non-concentricity, bending and bowing. It is a surprising result that the pressure ramping method of the first embodiment achieves the following: concentric hole shapes at the top and bottom of each hole, elimination of bending and elimination of bowing.

In accordance with a second embodiment, RF power ramping solves the problem of bending without damaging the photolithographic mask. In the second embodiment, the user interface 460 provides the computer 455 with a starting RF power level, an ending RF power level and an etch time.

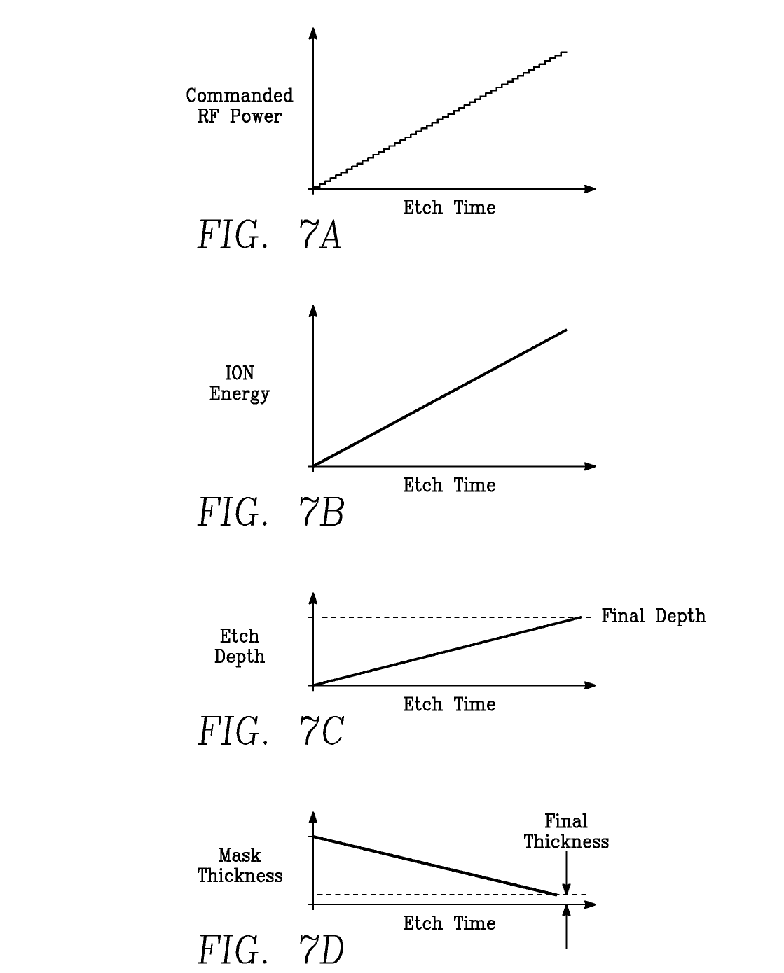

Referring to FIG. 7A, the computer 455 is programmed to command the system controller 450 to set the RF power (e.g., of the RF power generator 412 or 426) to the starting RF power level and continuously increase (ramp up) the RF power level at a computed rate. The rate is the difference between the starting and ending RF power levels divided by the etch time. FIG. 7A shows the commanded RF power level being ramped up in micro steps, each microstep corresponding to a digital control sample size of the system controller 450. The duration of each microstep is preferably less than the time required for the RF power to fully respond to a commanded power level change represented by a single microstep. The response of the measured ion energy level or actual RF power level is too slow to follow the individual microsteps of FIG. 7A, and therefore follows the smooth ramp of FIG. 7B. FIG. 7C depicts how the etch depth increases during the duration of the etch process. FIG. 7D depicts how the thickness of the photolithographic mask decreases at a sufficiently slow rate to leave a finite thickness at the end of the etch process. This finite thickness remains because the RF power level was kept low during the beginning of etch process, to conserve mask thickness, and did not reach a high level until the etch depth had increased so that a high RF power level was needed to prevent bending.

The RF power level or ion energy (FIG. 7B) is continually increasing to meet the latest microstep in the commanded RF power level pressure (FIG. 7A), and therefore follows a smooth continuous ramp trajectory as shown in the graph of FIG. 7B.

FIG. 8 depicts operation defined by the executable instructions of the memory 455-1 in accordance with the second embodiment corresponding to FIGS. 7A-7D. A first step is to determine the rate Rrf at which the pressure is to be ramped downwardly (block 810 of FIG. 8). The rate Rrf is computed as the difference between the starting and ending RF power levels divided by the etch time. The starting RF power level, the ending RF power level and the etch time are received from the user interface 460. The next step is to order the system controller 450 to initialize the RF power level to the starting RF power level (block 820 of FIG. 8). The controller 450 may accomplish this by controlling any of the RF power generators 412, 426. Next, the computer 455 outputs a succession of RF power level commands in increasing sequence of RF power levels as depicted in FIG. 7A (block 830 of FIG. 8). The operation is halted at the end of the etch time (block 840 of FIG. 8).

The starting RF power level may be the minimum required to perform etch while the hole depth is relatively shallow. The level is minimize to reduce or minimize sputtering of the photolithographic mask 115. The ending RF power level sufficient to prevent bending at the extreme depth (e.g., 2200 nm) of the hole, and may be as high as needed. In one example, the starting RF power level of the RF bias generator 426 was 1 kW and the ending RF power level was 7 kW.

The RF power ramping method of the second embodiment solves the problem of preventing bending without removing the photolithographic mask, due to the reduction in RF power level during the initial stage of the etch process, as described above. In addition, we have discovered that the foregoing process of ramping the RF power level solves the problems of non-concentricity, bending and bowing. It is a surprising result that the RF power level ramping method of the second embodiment achieves the following: concentric hole shapes at the top and bottom of each hole, elimination of bending and elimination of bowing.

In accordance with a third embodiment, the method of the first embodiment (FIGS. 5A-5D and 6) and the method of the second embodiment (FIGS. 7A-7D and 8) are performed simultaneously during processing of the same workpiece or wafer. In this third embodiment, the chamber pressure is ramped downwardly while simultaneously the RF power level is ramped upwardly. The third embodiment can provide the advantage of solving all the problems of etch selectivity, non-concentricity, bending and bowing in the same etch process.

While the foregoing is directed to embodiments of the present invention, other and further embodiments of the invention may be devised without departing from the basic scope thereof, and the scope thereof is determined by the claims that follow.

What is claimed is:

1. A method of processing a workpiece in a plasma reactor chamber, comprising:
defining a starting chamber pressure;
defining an ending chamber pressure at which a desired etch selectivity of an etch process to an underlying barrier layer is realized;
defining an etch time;
computing a pressure ramping rate as a difference between said starting and ending chamber pressures divided by said etch time;
providing in said chamber a plasma containing etchant species;
initializing a chamber pressure in said chamber at said starting chamber pressure; and
ramping said chamber pressure at said pressure ramping rate.

2. The method of claim 1 further comprising:
providing a user interface configured to receive values of said starting and ending chamber pressures;
controlling said chamber pressure with a digital control system in response to said user interface.

3. The method of claim 2 wherein said ramping comprises generating successive chamber pressure commands in said digital control system representing successive microsteps of decreasing pressure levels.

4. The method of claim 3 wherein the pressure difference between said successive microsteps is sufficiently small to cause said chamber pressure to decrease in a continuous ramp.

5. The method of claim 1 wherein said starting pressure level is one at which an etch process parameter is realized at a desired value.

6. The method of claim 5 wherein said etch process parameter is etch rate.

7. A computer readable medium having instructions for causing a computer to execute a method of processing a workpiece in a plasma reactor chamber, comprising:
defining a starting chamber pressure;
defining an ending chamber pressure at which a desired etch selectivity of an etch process to an underlying barrier layer is realized;
defining an etch time;
computing a pressure ramping rate as a difference between said starting and ending chamber pressures divided by said etch time;
providing in said chamber a plasma containing etchant species;
initializing a chamber pressure in said chamber at said starting chamber pressure; and
ramping said chamber pressure at said pressure ramping rate.

8. The computer readable medium of claim 7 wherein said ramping comprises generating successive chamber pressure commands in a digital control system representing successive microsteps of decreasing pressure levels.

9. The computer readable medium of claim 8 wherein the pressure difference between said successive microsteps is sufficiently small to cause said chamber pressure to decrease in a continuous ramp.

10. A method of processing a workpiece in a plasma reactor chamber comprising an RF power applicator, comprising:
defining a starting RF power level;
defining an ending RF power level sufficient to prevent bowing at the bottom of an etched opening;
defining an etch time;
computing an RF power ramping rate as a difference between said starting and ending RF power levels divided by said etch time;
providing in said chamber a plasma containing etchant species;
initializing an RF power level for said RF power applicator at said starting RF power level; and
ramping said RF power level pressure at said RF power ramping rate.

11. The method of claim 10 further comprising:
providing a user interface configured to receive values of said starting and ending RF power levels;
controlling said RF power level with a digital control system in response to said user interface.

12. The method of claim 11 wherein said ramping comprises generating successive RF power level commands in said digital control system representing successive microsteps of increasing RF power levels.

13. The method of claim 12 wherein a difference between successive microsteps is sufficiently small to cause said RF power level to increase in a continuous ramp.

14. The method of claim 10 wherein said starting RF power level exceeds a minimum RF power level for sustaining an etch process and wherein said ending RF power level is sufficient to prevent bowing near a bottom of an etched opening having an aspect ratio on the order of approximately 40:1.

15. The method of claim 10 further comprising:
defining a starting chamber pressure;
defining an ending chamber pressure at which a desired etch selectivity of an etch process to an underlying barrier layer is realized;
computing a pressure ramping rate as a difference between said starting and ending chamber pressures divided by said etch time;
initializing a chamber pressure in said chamber at said starting chamber pressure; and
ramping said chamber pressure at said pressure ramping rate.

16. The method of claim 15 further comprising controlling said chamber pressure with a digital control system and wherein said ramping comprises generating successive chamber pressure commands in said digital control system representing successive pressure microsteps of decreasing pressure levels.

17. The method of claim 16 wherein a difference between successive pressure microsteps is sufficiently small to cause said pressure level to decrease in a continuous ramp.

18. A computer readable medium having instructions for causing a computer to execute a method of processing a workpiece in a plasma reactor chamber, comprising:
defining a starting RF power level;
defining an ending RF power level sufficient to prevent bowing at the bottom of an etched opening;
defining an etch time;
computing an RF power ramping rate as a difference between said starting and ending RF power levels divided by said etch time;
providing in said chamber a plasma containing etchant species;
initializing an RF power level for said RF power applicator at said starting RF power level; and
ramping said RF power level pressure at said RF power ramping rate.

19. The computer readable medium of claim 18 wherein said ramping comprises generating successive RF power level commands in a digital control system representing successive microsteps of increasing RF power levels.

20. The computer readable medium of claim 19 wherein a difference between successive microsteps is sufficiently small to cause said RF power level to increase in a continuous ramp.
